(19) United States
(12) Patent Application Publication
(10) Pub. No.: US 2008/0252387 A1
(43) Pub. Date: Oct. 16, 2008

(54) OSCILLATOR

(75) Inventor: Hirohito Higashi, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki-shi (JP)

(21) Appl. No.: 12/143,253

(22) Filed: Jun. 20, 2008

Related U.S. Application Data
(63) Continuation of application No. PCT/JP2005/023372, filed on Dec. 20, 2005.

(51) Int. Cl. H03K 3/03

(52) U.S. Cl. 331/57

(57) ABSTRACT

There is provided an oscillator having first and second oscillating units (301a, 301c) outputting signals having phases in a mutually orthogonal relationship, in which simultaneous connection of a plurality of current sources to the first and second oscillating units does not occur, and only one current source (303a) is connected thereto at any point of time. For example, the current source is connected in common to the first and second oscillating units. The first and second oscillating units each have a CML type differential amplifier including a delay element of a resistor and a capacitor and form a ring oscillator to be ring connected.

### TECHNICAL FIELD

The present invention relates to an oscillator.

### BACKGROUND ART

FIG. 15A is a diagram showing a structure example of a voltage controlled ring oscillator. The voltage controlled ring oscillator is a voltage Controlled Oscillator (VCO). A plurality of differential amplifiers 1501 are ring connected. A plurality of variable resistors 1502 are connected respectively to the plurality of differential amplifiers 1501. A plurality of current sources 1503 are connected respectively to the plurality of differential amplifiers 1501. A CR ring element 1504 has a differential amplifier 1501, a variable resistor 1502 and a current source 1503. For example, four CR ring elements 1504 are ring connected.

FIG. 15B is a circuit diagram showing a structure example of the CR ring element 1504 of FIG. 15A. Hereinafter, a MOS field effect transistor will be simply referred to as a transistor. The CR ring element 1504 inputs differential signals from non-inverting input terminal I+ and an inverting input terminal I−, amplifies the differential signals, and outputs the amplified differential signals from a non-inverting output terminal O+ and an inverting output terminal O−. The differential signals are two signals having phases mutually inverted by 180 degrees. Parasitic capacitors are connected to the non-inverting output terminal O+ and the inverting output terminal O−, respectively. The non-inverting input terminal I+ is connected to a gate of an N-channel transistor 1511a, and the inverting input terminal I− is connected to a gate of an N-channel transistor 1511b. The non-inverting output terminal O+ is connected to a drain of the transistor 1511b, and the inverting output terminal O− is connected to a drain of the transistor 1511a. A P-channel transistor 1512a has a gate connected to a control voltage Vcntl, and a source connected to a power supply voltage, and a drain connected to the drain of the transistor 1511a, thereby forming a load resistor. A P-channel transistor 1512b has a gate connected to the control voltage Vcntl, a source connected to the power supply voltage, and a drain connected to the drain of the transistor 1511b, thereby forming a load resistor. The transistors 1512a and 1512b are variable resistors which correspond to the variable resistors 1502 of FIG. 15A and are controlled by the voltage Vcntl. The current source 1503 is connected between a mutual connection point of sources of the transistors 1511a and 1511b and ground, and allows a tail current Iref1 to flow. In the CR ring element 1504, a delay amount of output signals is determined by CR of a capacitor and a resistor. By changing the variable resistors 1512a and 1512b by the voltage Vcntl, an oscillation frequency of the ring oscillator can be controlled.

In recent years, while increase in speed of signals is in advance, achieving low power consumption is also considered as an important theme. The aforementioned VCO is used for a Phase Lock Loop (PLL) circuit. In the case of the PLL circuit, it is the VCO that dominates the current consumption thereof. Suppression of power consumption of the VCO leads to suppression of the power of the PLL circuit, and hence is an important problem.

Further, there is a four-phase oscillator having a four-phase multi-ring oscillator unit constituted of first to fourth transistor pairs, a resistor as a load for an oscillation signal, a transistor varying a current flowing through the load resistor and the transistors of the four-phase multi-ring oscillator unit by a control voltage, a transistor varying a counteracting current so as to make the current flowing through the load resistor become constant, a transistor isolating the current of the oscillation signal and the counteracting current, and a constant current source allowing a constant current to flow.

Further, there is an oscillating circuit formed by connecting an odd number of stages of negative logic circuits constituted of field effect transistors and connecting an output of a last stage to an input of a first stage, the oscillating circuit characterized in that at least one of a power supply potential and a ground potential of the negative logic circuit is driven by a constant current circuit.

Further, there is a voltage controlled oscillator including an input unit receiving an input signal, a ring oscillator circuit having first to third stages of inverters each constituted of a P-channel MOS transistor and an N-channel MOS transistor, a first current source constituted of a first conductive type MOS transistor supplying a current to each inverter of the ring oscillator, and a second current source pulling out a current from each inverter of the ring oscillator, the second current source constituted of a second conductive type MOS transistor different from the first conductive type.

Further, there is a semiconductor integrated circuit keeping a gate voltage of a constant current generating transistor constant and allowing a ring oscillator of a main oscillating circuit, which needs the constant current, to operate stably.

However, in the case of the voltage controlled ring oscillator, it is necessary that each CR ring element 1504 satisfies an oscillating condition. Accordingly, each CR ring element 1504 has the current source 1503 of the tail current Iref1. There is a problem such that, as the number of stages of the CR ring elements 1504 is increased, the number of current sources 1503 increases too, and the current consumption therein increases in proportion thereto.

### SUMMARY OF THE INVENTION

According to one aspect of the present invention, there is provided an oscillator having first and second oscillating units outputting signals having phases in a mutually orthogonal relationship, in which simultaneous connection of a plurality of current sources to the first and second oscillating units does not occur, and only one current source is connected thereto at any point of time.

### BRIEF DESCRIPTION OF THE DRAWINGS

FIG. 1 is a diagram showing a structure example of a fast I/O (input/output) circuit according to a first embodiment of the present invention;

FIG. 2 is a diagram showing a structure example of an RF oscillating circuit according to the first embodiment;

FIG. 3A is a circuit diagram showing a structure example of a VCO of FIG. 1 and FIG. 2;

FIG. 3B is a circuit diagram showing a structure example of a CR ring element of FIG. 3A;

FIG. 4 is a chart showing a waveform example of a half cycle of the VCO when seeing with one stage of a CR ring element;

FIG. 5 is a diagram showing phases of output signals of respective ring elements of the VCO of FIG. 3A;

FIG. 6A is a circuit diagram showing a structure example of a VCO according to the second embodiment of the present invention;

FIG. 6B is a circuit diagram showing a structure example of a ring element of FIG. 6A;

FIG. 6C is a circuit diagram showing another structure example of the ring element of FIG. 6A;

FIG. 7A is a circuit diagram showing a structure example of a VCO according to a third embodiment of the present invention;

FIG. 7B is a circuit diagram showing a structure example of a ring element of FIG. 7A;

FIG. 7C is a circuit diagram showing another structure example of the ring element of FIG. 7A;

FIG. 8A is a circuit diagram showing a structure example of a VCO according to a fourth embodiment of the present invention;

FIG. 8B is a circuit diagram showing a structure example of a ring element of FIG. 8A;

FIG. 9 is a circuit diagram showing a structure example of a VCO according to a fifth embodiment of the present invention;

FIG. 10 is a circuit diagram showing a structure example of a VCO according to a sixth embodiment of the present invention;

FIG. 11 is a timing chart showing an operation of a circuit of FIG. 10;

FIG. 12A is a circuit diagram showing a structure example of a quadrature LC-VCO;

FIG. 12B is a circuit diagram showing a structure example of the LC-VCO of FIG. 12A;

FIG. 13A is a circuit diagram showing a structure example of a VCO according to a seventh embodiment of the present invention;

FIG. 13B is a circuit diagram showing a structure example of the LC-VCO of FIG. 13A;

FIG. 14 is a circuit diagram showing a structure example of a VCO according to an eighth embodiment of the present invention;

FIG. 15A is a diagram showing a structure example of a voltage-controlled ring oscillator; and

FIG. 15B is a circuit diagram showing a structure example of a CR ring element of FIG. 15A.

### DETAILED DESCRIPTION OF THE PREFERRED EMBODIMENTS

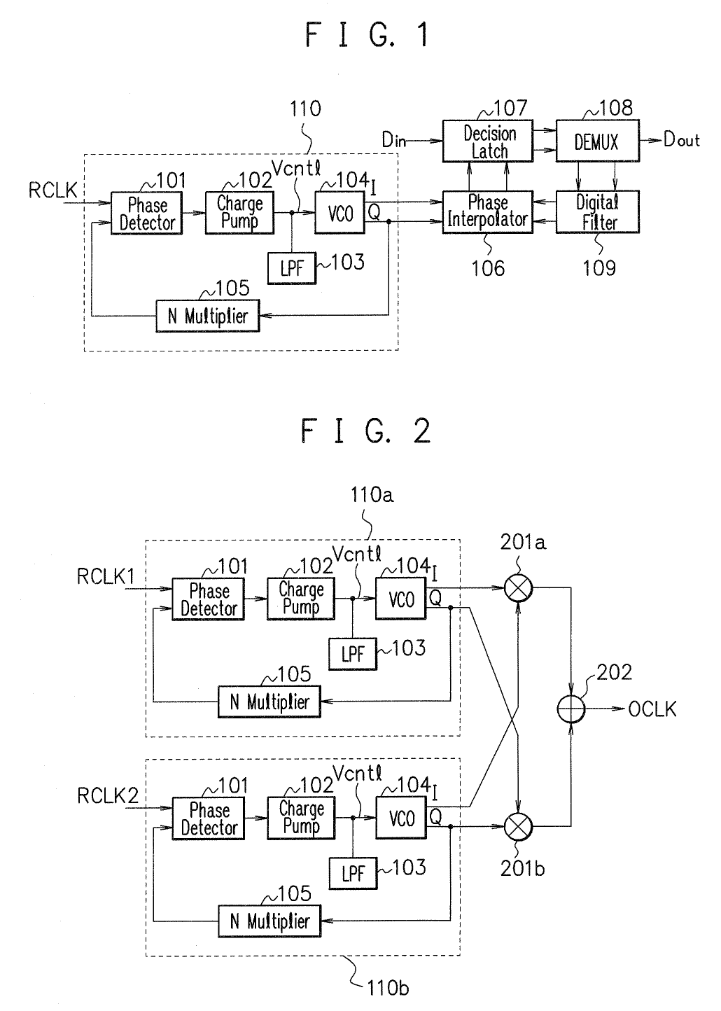

FIG. 1 is a diagram showing a structure example of a fast I/O (input/output) circuit according to a first embodiment of the present invention. In the case of the fast I/O circuit, a driver (Tx) and a receiver (Rx) require a clock with a frequency that is half the data rate thereof, and this clock is generated by a PLL circuit 110. The PLL circuit 110 has a phase detector 101, a charge pump 102, a loop filter (LPF) 103, a voltage controlled oscillator (VCO) 104, and a multiplier 105. The phase detector 101 compares a reference clock RCLK with an output clock (feedback clock) from the multiplier 105, and outputs a pulse width according to a phase error thereof to the charge pump 102. The charge pump 102 allows a current according to this pulse width to flow to the LPF 103. The LPF 103 is a low-pass filter, which smoothes this error signal. The VCO 104 oscillates by a frequency according to this smoothed voltage Vcntl, and outputs an I signal and a Q signal. For example, the I signal is a differential signal of 0 degree and 180 degrees, and the Q signal is a differential signal of 90 degrees and 270 degrees. The multiplier 105 outputs a signal which is N times the frequency of one signal outputted by the VCO 104 to the phase detector 101. Consequently, when the phase error detected by the phase detector 101 becomes 0 (zero), the PLL circuit 110 changes to a lock state (steady state), and becomes possible to obtain stable synchronized clocks (I signal and Q signal) which are N times the frequency of the reference clock RCLK.

A phase interpolator 106 mixes output signals of the VCO 104 and a digital filter 109, and outputs the mixed signal to a decision latch 107. The decision latch 107 latches data Din in a serial format and outputs the data to a demultiplexer 108. The demultiplexer 108 converts the data from the serial format to a parallel format, and outputs data Dout. The digital filter 109 filters output data of the demultiplexer 108, and outputs the data to the phase interpolator 106. Thus, the latch timing of the decision latch 107 can be adjusted to appropriate timing at which the data Din are stable.

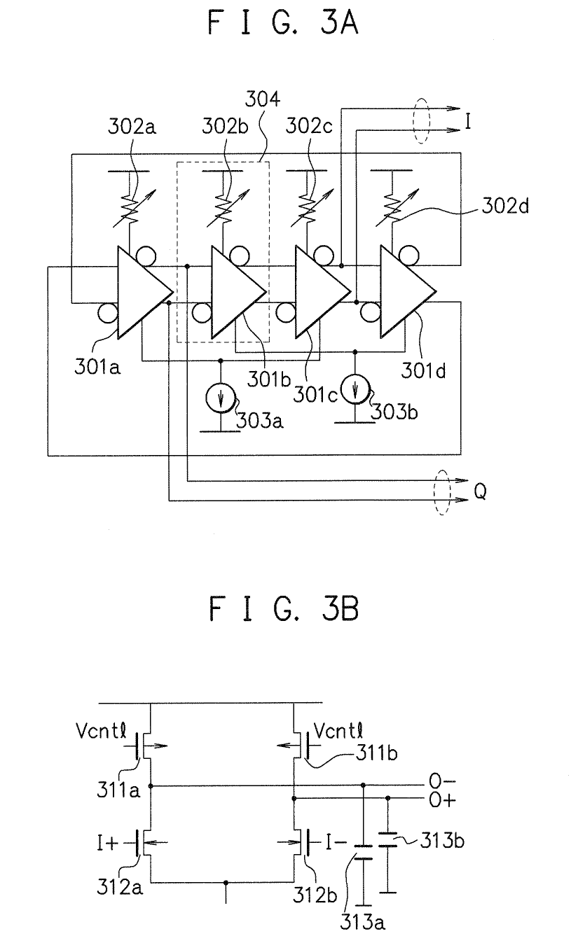

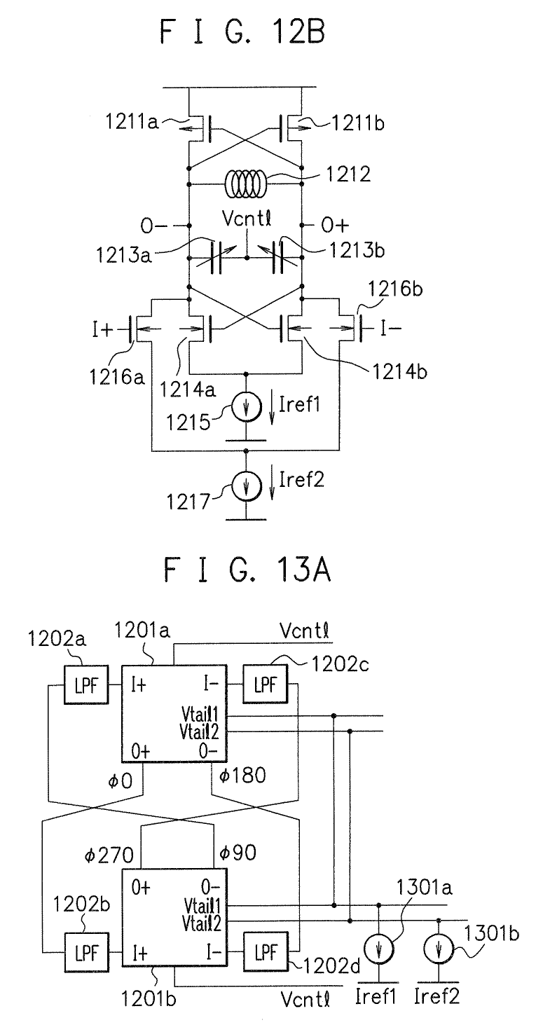

For the VCO 104 used in the fast I/O circuit, an LC-VCO (FIG. 12A, FIG. 12B, and so on) using an LC resonance or a ring oscillator type VCO (FIG. 3A, FIG. 3B, or the like), which applies positive feedback to a current mode logic (CML) type differential amplifier, is used. Particularly, in the case of application in an RF band (over a few GHz), the ring oscillator type VCO cannot provide the band, and hence the LC-VCO is used. The LC-VCO having a phase relationship of 90 degrees is generally called a quadrature LC-VCO.

FIG. 2 is a diagram showing a structure example of an RF oscillating circuit according to this embodiment. The two PLL circuits 110a and lob have structures identical to the PLL circuit 110 of FIG. 1. The PLL circuit 110a inputs a reference clock RCLK1 and outputs an I signal and a Q signal having frequencies which are N times the reference clock. The PLL circuit 110b inputs a reference clock RCLK2 and outputs an I signal and a Q signal having frequencies which are N times the reference clock. A multiplier 201a multiplies the I signals of the PLL circuits 110a and 110b and outputs them. A multiplier 201b multiplies the Q signals of the PLL circuits 110a and 110b and outputs them. An adder 202 adds output signals of the multipliers 201a and 201b and outputs a clock OCLK having a high frequency.

Further, in an RF communication circuit, a carrier for demodulating a signal is required on the transmitting side, and the VCO 104 is required as a signal source for a mixer thereof. On the receiving side, a carrier with the same frequency is required for demodulating this signal, and the VCO is also required therein. In the mixer, a desired signal is created by multiplying signals (sin wave and cos wave) in an orthogonal relationship, and thus in the VCO 104 a multi-phase signal having a phase difference of 90 degrees is required. When the band is high also in the field of RF, the LC-VCO is often used rather than the ring oscillator type VCO.

This embodiment is applicable to a VCO used for a fast I/O circuit and RF, as well as a PLL circuit or the like using the VCO.

FIG. 3A is a circuit diagram showing a structure example of the VCO 104 of FIG. 1 and FIG. 2. This VCO 104 is a voltage controlled ring oscillator (ring oscillator type VCO). A plurality (four for example) of differential amplifiers 301a, 301b, 301c, 301d are ring connected. A plurality (four for example) of load resistors 302a, 302b, 302c, 302d are connected between the plurality of differential amplifiers 301a to 301d and a power supply voltage respectively, and are variable resistors complying with a control voltage. A current source 303a is connected between the differential amplifiers 301a and 301c and ground. A current source 303b is connected between the differential amplifiers 301b and 301d and the ground.

A CR ring element (oscillating unit) 304 has, for example, one differential amplifier 301b and one load resistor 302b. The four differential amplifiers 301a to 301d have identical structures, and the four load resistors 302a to 302d also have identical structures. The four CR ring element 304 having identical structures are ring connected. The differential amplifiers 301a to 301d input differential signals, and amplify and output the differential signals. The differential signals are two signals having phases mutually inverted by 180 degrees. Output differential signals of each of the differential amplifiers 301a to 301d have a phase difference resulting from dividing the 180 degrees by the number of differential amplifiers 301a to 301d. For example, the differential amplifier 301c outputs differential signals of 0 degree and 180 degrees as the I signals. The differential amplifier 301d outputs differential signals of 45 degrees and 225 degrees. The differential amplifier 301a outputs differential signals of 90 degrees and 270 degrees as the Q signals. The differential amplifier 301b outputs differential signals of 135 degrees and 315 degrees.

The differential amplifiers 301a and 301c output differential signals having phases in a mutually orthogonal relationship (phase difference of 90 degrees). The current source 303a is connected in common to the differential amplifiers 301b and 301d. Further, the differential amplifiers 301b and 301d output differential signals having phases in a mutually orthogonal relationship (phase difference of 90 degrees). The current source 303b is connected in common to the differential amplifiers 301b and 301d.

FIG. 3B is a circuit diagram showing a structure example of the CR ring element 304 of FIG. 3A. The CR ring element 304 has a CML type differential amplifier, and inputs differential signals from a non-inverting input terminal I+ and an inverting input terminal I−, amplifies the differential signals, and outputs the amplified differential signals from a non-inverting output terminal O+ and an inverting output terminal O−. To the non-inverting output terminal O+ and the inverting output terminal O−, a parasitic capacitor 313b and a parasitic capacitor 313a are connected respectively. The non-inverting input terminal I+ is connected to a gate of an N-channel transistor 312a. The inverting input terminal I− is connected to a gate of an N-channel transistor 312b. The inverting output terminal O− is connected to a drain of the transistor 312a. The non-inverting output terminal O+ is connected to a drain of the transistor 312b. The P-channel transistors 311a and 311b each have a gate connected to a control voltage Vcntl and a source connected to the power supply voltage. A drain of the transistor 311a is connected to the drain of the transistor 312a, and a drain of the transistor 311b is connected to the drain of the transistor 312b. The transistors 311a and 311b correspond to the variable resistor 302b of FIG. 3A for example, and have a resistance value that changes according to the control voltage Vcntl. A mutual connection point of sources of the transistors 312a and 312b is connected to the current source 303b of FIG. 3A for example. In the CR ring element (delay element) 304, a delay amount of an output signal is determined by CR of a capacitor and a resistor. By changing the variable resistors 311a and 311b by the voltage Vcntl, the oscillating frequency of the ring oscillator can be controlled.

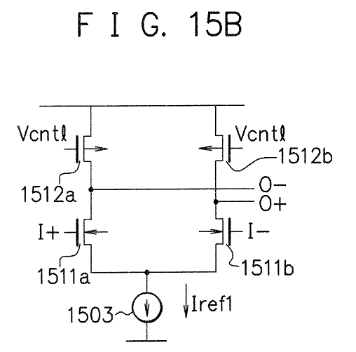

As described above, a tail current Iref1 for the differential amplifiers 301a and 301c with a phase difference in an orthogonal relationship of 90 degrees is made to be shared by the current source 303a, and a tail current Iref1 for the differential amplifiers 301b and 302d is made to be shared by the current source 303b. Assuming that each of the current values of the tail current sources 303a and 303b is the same as the current value of the current source 1503 of FIG. 15A, in the VCO of this embodiment the number of tail current sources as the entire VCO becomes half as compared to the VCO of FIG. 15A, and this means that the total current consumption amount becomes half as well.

As shown in FIG. 5, the ring oscillator type VCO has a delay amount per stage being phase shifted by 45 degrees each, and hence the tail current source is shared by every other ring stage. The VCO of this embodiment satisfies the same oscillation condition and oscillation frequency as those of the VCO of FIG. 15A. Then, the reason why the goal thereof can be achieved by the same condition as the VCO of FIG. 15A even with the current sources being shared will be explained below.

First, the oscillation condition of the VCO of FIG. 15A will be explained. The ring oscillator type VCO is oscillated by connecting a plurality of stages (four stages or more) of CML type differential amplifiers and applying positive feedback thereto. When four stages of ring elements are connected, the delay value of each ring element is such that a phase is shifted by ⅛ of an oscillating cycle of the VCO, in other words, in a state such that the phase is rotated 45 degrees each. When the output is pulled out from every other stage of the ring elements, the I signal and the Q signal having a phase relationship of 90 degrees can be obtained. The oscillation frequency fo is represented by the following equation when the number of stages of the ring elements is N stages, and the delay value (CR delay value) of each ring element is τ.

fo=1/(2×N×τ)∝Iref1

Here, Iref1 means the current value of the tail current source 1503 of each ring element. The condition for the ring oscillator type VCO to oscillate is determined by a gain and a phase margin of each ring element. A gain A needed for each ring element derived from a phase margin for applying positive feedback is represented by the following equations.

tan⁻¹(ωf/ωO)=45 degrees

A=√2

Here, ωf and ωO denote an oscillation frequency and a frequency of a 3-dB band respectively. Each ring element has a phase rotating 45 degrees in the case of the four-stage differential ring oscillator type VCO, and therefore, to oscillate by this condition means that presence of √2 gain at the minimum in each stage allows oscillation.

The ring oscillator type VCO of FIGS. 3A and 3B is nothing more or less than a differential amplifier when seeing the operation with one stage of the CR ring element 304. The differential amplifier is a circuit that amplifies a difference of inputted voltages by multiplication of a gain, and fluctuation in output waveform does not occur as a matter of course as long as the difference voltage is constant. With the differential amplifier, as shown in FIG. 5, signals 501 with output phases of 0 degree and 180 degrees are obtained, where signals most distant in phase from the output signals 501 are certainly signals 503 of 90 degrees and 270 degrees.

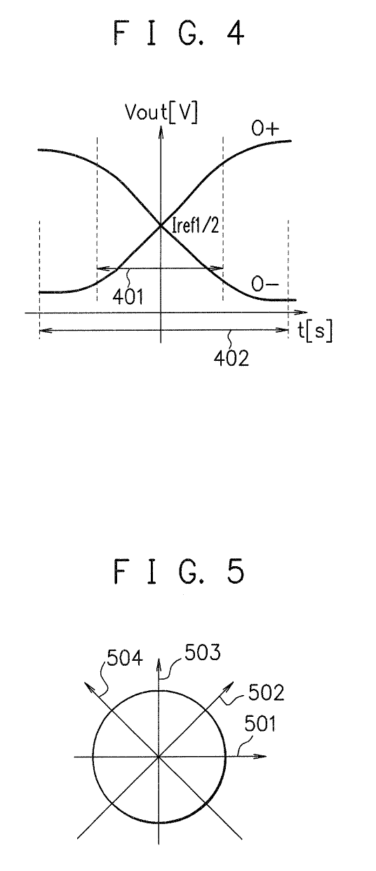

FIG. 4 is a diagram showing a waveform example of a half cycle of the VCO when seen with one stage of the CR ring element 304. A period in which an amplifying operation is required is only a period 401 in which the input voltage fluctuates from a high level to a low level or from a low level to a high level. This period 401 requires an operation of amplifying by the differential amplifier, and hence the current source needs to be active. However, after the amplifying operation is finished, the signal is retained at high level or low level for a predetermined period. Accordingly, in that period, there is no problem for the current source to be in an off state. The output voltage may just be on hold. The output signal level thereof is retained by the capacitors 313a and 313b of FIG. 3B. In a different point of view, actually this hold period is just the moment that a signal with an orthogonal phase is performing an amplifying operation, and this is certainly none other than a signal in a phase difference relationship of 90 degrees. The period 401 is an amplifying operation period of the first stage ring element of FIG. 3A, and a period 402 is an amplifying operation period of one stage of a ring element of FIG. 15A. Therefore, in this embodiment, the sharing of the tail current source allows to effectively use the current source only for an amplifying operation in the entire one cycle, and consequently the total current of the VCO can be reduced in half.

FIG. 5 is a diagram showing phases of output signals of each ring element 304 of the VCO of FIG. 3A. The differential amplifier 301c outputs the differential signals 501 of 0 degree and 180 degrees. The differential amplifier 301a outputs the differential signals 503 of 90 degrees and 270 degrees orthogonal to the differential signals 501. These differential amplifiers 301a and 301c share the current source 303a since they perform an amplifying operation in a different period as described above.

Similarly, the differential amplifier 301d outputs differential signals 502 of 45 degrees and 225 degrees. The differential amplifier 301b outputs differential signals 504 at 135 degrees and 315 degrees orthogonal to the differential signals 502. These differential amplifiers 301b and 301d share the current source 303b since they perform an amplifying operation in a different period as described above.

By the differential amplifiers having orthogonal output signals sharing the current sources, the current sources can be used effectively across one cycle.

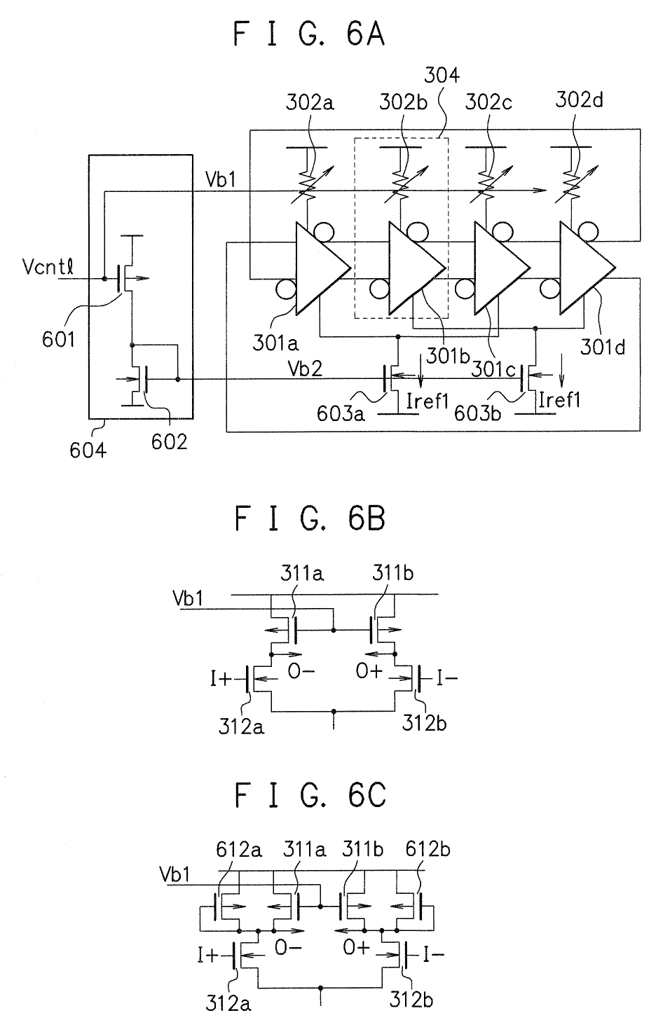

FIG. 6A is a circuit diagram showing a structure example of the VCO 104 (FIG. 1 and FIG. 2) according to a second embodiment of the present invention. Differences of FIG. 6A from FIG. 3A will be explained. A bias circuit 604 has transistors 601 and 602. The P-channel transistor 601 has a gate connected to the control voltage Vcntl and a source connected to the power supply voltage. The N-channel transistor 602 has a gate and a drain connected to a drain of the transistor 601 and a source connected to the ground. The bias circuit 604 outputs bias voltages Vb1 and Vb2. The voltage Vb1 is the same voltage as the control voltage Vcntl. The voltage Vb2 is a voltage at a mutual connection point of the drains of the transistors 601 and 602. An N-channel transistor 603a corresponds to the current source 303a of FIG. 3A, and has a gate connected to the gate of the transistor 602, a drain connected to the differential amplifiers 301a and 301c, and a source connected to the ground. An N-channel transistor 603b corresponds to the current source 303b of FIG. 3A, and has a gate connected to the gate of the transistor 602, a drain connected to the differential amplifiers 301b and 301d, and a source connected to the ground. The transistors 602, 603a and 603b form a current mirror circuit. A drain current Iref1 flows through the transistors 603a and 603b. The variable resistors 302a to 302d each have a resistance value that changes according to the voltage Vb1. The voltages Vb1 and Vb2 are values variable according to the control voltage Vcntl. By controlling the voltage Vcntl, the oscillation frequency of the ring oscillator can be controlled.

FIG. 6B is a circuit diagram showing a structure example of the ring element 304 of FIG. 6A. The structure of FIG. 6B is the same as the structure of FIG. 3B. The gate voltage Vb1 of the transistors 311a and 311b is the same as the control voltage Vcntl.

FIG. 6C is a circuit diagram showing another structure example of the ring element 304 of FIG. 6A. The circuit of FIG. 6C is made by adding transistors 612a and 612b to the circuit of FIG. 6B. The P-channel transistor 612a has a source connected to the power supply voltage and a gate and a drain connected to the drain of the transistor 312a. The P-channel transistor 612b has a source connected to the power supply voltage, and a gate and a drain connected to the drain of the transistor 312b.

Similarly to the first embodiment, this embodiment is a ring oscillator type VCO in which differential amplifiers in a phase difference relationship of 90 degrees share tail current sources. Two examples of transistors as loads are shown, which are P-channel bias type of FIG. 6B and symmetric load type of FIG. 6C. The load resistors 302a to 302d and the tail current sources 603a, 603b are both controlled simultaneously or only one side of them is controlled, according to the control voltage Vcntl. That is, one of the voltages Vb1 and Vb2 is a variable value and the other one may be a fixed value.

As above, in this embodiment, by the differential amplifiers having a phase difference in an orthogonal relationship of 90 degrees sharing the tail current sources in the differential ring oscillator type VCO of CML type, the power supply current can be cut in half. The tail current sources 303a, 303b are constituted of the N-channel transistors 603a, 603b. The bias voltages Vb1 and Vb2 supplied to the load resistors and the tail current sources are variable or fixed according to the control voltage Vcntl.

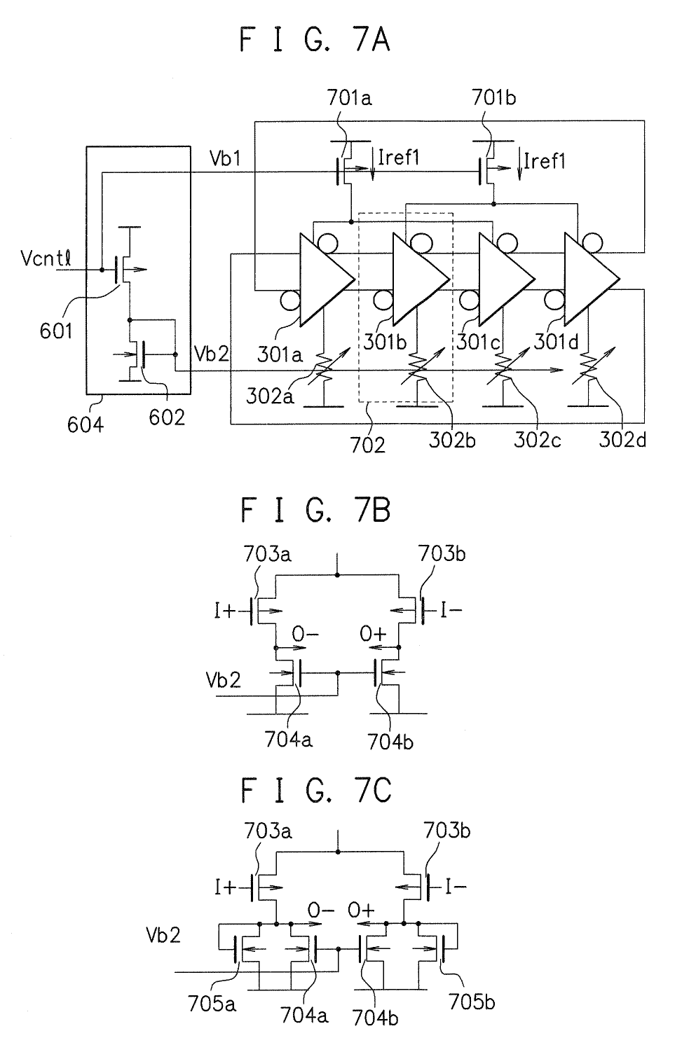

FIG. 7A is a circuit diagram showing a structure example of the VCO 104 (FIG. 1 and FIG. 2) according to a third embodiment of the present invention. Differences of FIG. 7A from FIG. 6A will be explained. The circuit of FIG. 7A is made by reversing the positions of the load resistors and the current sources in the circuit of FIG. 6A. A P-channel transistor 701a has a gate connected to the voltage Vb1, a source connected to the power supply voltage, and a drain connected to the differential amplifiers 301a and 301c. A P-channel transistor 701b has a gate connected to the voltage Vb1, a source connected to the power supply voltage, and a drain connected to the differential amplifiers 301b and 301d. The transistors 701a and 701b form current sources of a current mirror, and allow a drain current Iref1 to flow. Load resistors 302a to 302d are connected respectively between the differential amplifiers 301a to 301d and the ground, and each have a resistance value that changes according to the voltage Vb2. A ring element 702 has the differential amplifier 301b and the load resistor 302b for example. Four stages of identical ring elements 702 are connected.

FIG. 7B is a circuit diagram showing a structure example of the ring element 702 of FIG. 7A. The P-channel transistor 703a has a gate connected to a non-inverting input terminal I+, a source connected to the drain of the transistor 701b of FIG. 7A for example, and a drain connected to an inverting output terminal O−. The P-channel transistor 703b has a gate connected to an inverting input terminal I−, a source connected to the drain of the transistor 701b of FIG. 7A for example, and a drain connected to a non-inverting output terminal O+. An N-channel transistor 704a has a gate connected to the voltage Vb2, a source connected to the ground, and a drain connected to the inverting output terminal O−. An N-channel transistor 704b has a gate connected to the voltage Vb2, a source connected to the ground, and a drain connected to the non-inverting output terminal O+. The transistors 704a and 704b correspond to the load resistor 302b for example.

FIG. 7C is a circuit diagram showing another structure example of the ring element 702 of FIG. 7A. The circuit of FIG. 7C is made by adding transistors 705a and 705b to the circuit of FIG. 7B. The N-channel transistor 705a has a gate and a drain connected to the inverting output terminal O−, and a source connected to the ground. The N-channel transistor 705b has a gate and a drain connected to the non-inverting output terminal O+ and a source connected to the ground.

Similarly to the first and second embodiments, this embodiment is a ring oscillator type VCO in which differential amplifiers in a phase difference relationship of 90 degrees share tail current sources, and is the case where the current sources 701a, 701b are connected to the power supply voltage side. When a circuit is structured mainly with P-channel transistors, the band drops as compared to the case of being structured mainly with N-channel transistors. However, the 1/f noise characteristic becomes advantageous, and hence the jitter becomes small.

In the differential ring oscillator type VCO of CML type of this embodiment, by the differential amplifiers in an orthogonal relationship of 90 degrees sharing the tail current sources, the power supply current can be cut in half. The tail current sources 701a, 701b are P-channel transistors. The bias voltages Vb1 and Vb2 supplied to the load resistors and the tail current sources are variable or fixed according to the control voltage Vcntl.

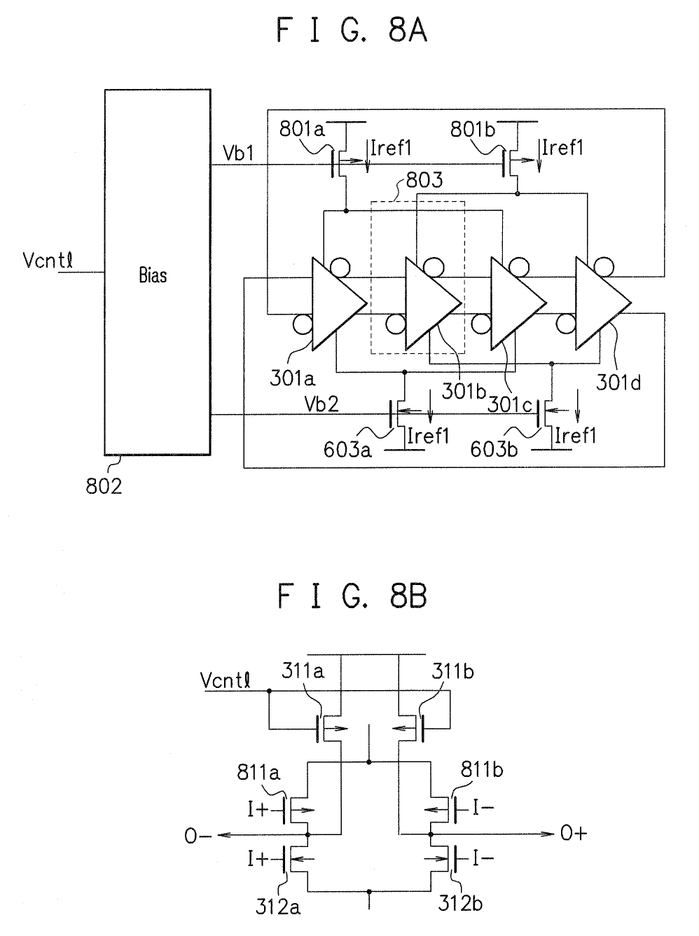

FIG. 8A is a circuit diagram showing a configuration example of the VCO 104 (FIG. 1 and FIG. 2) according to a fourth embodiment of the present invention. Differences of FIG. 8A from FIG. 6A will be explained. The circuit of FIG. 8A is made by adding transistors 801a and 801b to the circuit of FIG. 6A. A bias circuit 802 outputs voltages Vb1 and Vb2 according to the control voltage Vcntl. The P-channel transistor 801a has a gate connected to the voltage Vb1, a source connected to the power supply voltage, and a drain connected to the differential amplifiers 301a and 301c. The P-channel transistor 801b has a gate connected to the voltage Vb1, a source connected to the power supply voltage, and a drain connected to the differential amplifiers 301b and 301d. The transistors 801a and 801b are current sources of a current mirror, and allow a current Iref1 to flow. The differential amplifiers 301a and 301c are connected to the common current source 801a. The differential amplifiers 301b and 301d are connected to the common current source 801b. Here, the differential amplifiers 301a to 301d include the variable load resistors 302a to 302d of FIG. 6A. A ring element 803 has the differential amplifier 301b for example. Four stages of identical ring elements 803 are connected.

FIG. 8B is a circuit diagram showing a structure example of the ring element 803 of FIG. 8A. Differences of FIG. 8A from FIG. 3B will be explained. The circuit of FIG. 8B is made by adding transistors 811A and 811b to the circuit of FIG. 3B. The P-channel transistor 811a has a gate connected to the non-inverting input terminal I+, a drain connected to the inverting output terminal O−, and a source connected to the drain of the transistor 801b of FIG. 8A for example. The P-channel transistor 811b has a gate connected to the inverting input terminal I−, a drain connected to the non-inverting output terminal O+, and a source connected to the drain of the transistor 801b of FIG. 8A for example.

Similarly to the first to third embodiments, this embodiment is a ring oscillator type VCO in which differential amplifiers in a phase relationship of 90 degrees share a tail current source, and has a circuit structure of LVDS (low voltage differential signaling) type. The current sources 801a, 801b are connected to the power supply voltage side, the current sources 603a, 603b are connected to the ground side, and the differential amplifiers 301a to 301d are sandwiched by the current sources 801a, 801b and the current sources 603a, 603b. In this case, the currents of the both current sources 801a, 801b, 603a, 603b change simultaneously according to the control voltage Vcntl.

In the differential ring oscillator type VCO of CML type of this embodiment, by the differential amplifiers in an orthogonal relationship of 90 degrees sharing the tail current sources, the power supply current can be cut in half. The VCO has the current sources having the same current values respectively on the power supply voltage side and the ground side. The bias voltages supplied to the load resistors and the tail current sources are variable or fixed according to the control voltage Vcntl.

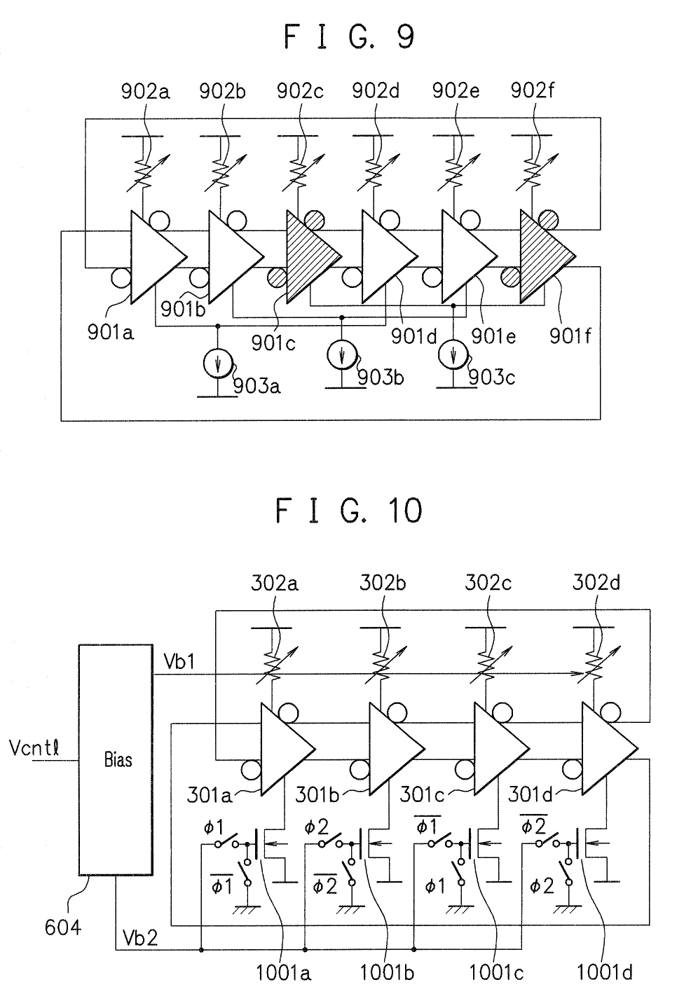

FIG. 9 is a circuit diagram showing a structure example of the VCO 104 (FIG. 1 and FIG. 2) according to a fifth embodiment of the present invention. While the ring oscillator type VCO connecting the four stages of ring elements is shown in the first to fourth embodiments, a ring oscillator type VCO connecting six stages of ring elements is shown in this embodiment. Six differential amplifiers 901a to 901f are ring connected. Variable load resistors 902a to 902f are connected respectively between the differential amplifiers 901a to 901f and the power supply voltage, and each have a resistance value that changes according to the control voltage Vcntl. A current source 903a is connected between the differential amplifiers 901c, 901f and the ground. A current source 903b is connected between the differential amplifiers 901b, 901e and the ground. A current source 903c is connected between the differential amplifiers 901c, 901f and the ground. The current sources 903a to 903c allow the same current Iref1 to flow.

For example, the differential amplifier 901a outputs differential signals of 0 degree and 180 degrees, the differential amplifier 901b outputs differential signals of 30 degrees and 210 degrees, the differential amplifier 901c outputs differential signals of 60 degrees and 240 degrees, the differential amplifier 901d outputs differential signals of 90 degrees and 270 degrees, the differential amplifier 901e outputs differential signals of 120 degrees and 300 degrees, and the differential amplifier 901f outputs differential signals of 150 degrees and 330 degrees.

The differential amplifiers 901a and 901d output differential signals having phases in a mutually orthogonal relationship, and hence can be connected to the common current source 903a. The differential amplifiers 901b and 901e output differential signals having phases in a mutually orthogonal relationship, and hence can be connected to the common current source 903b. The differential amplifiers 901c and 901f output differential signals having phases in a mutually orthogonal relationship, and hence can be connected to the common current source 903c.

When the number of stages of the ring elements increases, the phase shift amount per ring stage changes. However, also in this case, when the phase difference relationship of 90 degrees exists, the ring elements thereof can share a current source, and the current consumption amount can be cut in half.

Similarly to the first to fourth embodiments, in the differential ring oscillator type VCO of CML type of this embodiment, by the differential amplifiers in an orthogonal relationship of 90 degrees sharing the tail current sources, the power supply current can be cut in half. The delay amount of each ring element is determined uniquely as a value resulting from dividing 180 degrees by the number of ring elements. When this delay value is a number that can be divided by 90 degrees, an orthogonal relationship of 90 degrees is established, and sharing of a tail current source becomes possible. The bias voltages supplied to the load resistors and the tail current sources are variable or fixed according to the control voltage Vcntl.

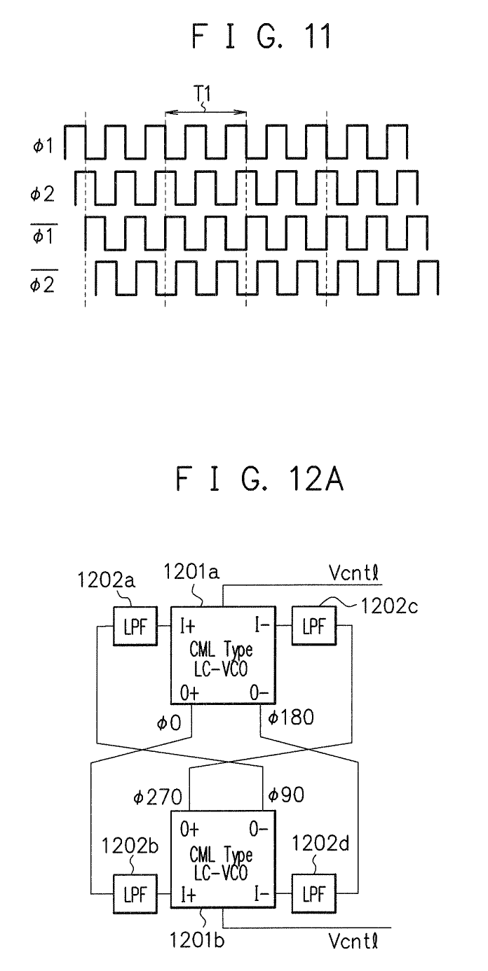

FIG. 10 is a circuit diagram showing a structure example of the VCO 104 (FIG. 1 and FIG. 2) according to a sixth embodiment of the present invention, and FIG. 11 is a timing chart showing an operation thereof. Differences of FIG. 10 from FIG. 6A will be explained. Transistors 1001a to 1001d are provided instead of the transistors 603a, 603b of FIG. 6A. The N-channel transistor 1001a has a source connected to the ground and a drain connected to the differential amplifier 301a. The N-channel transistor 1001b has a source connected to the ground and a drain connected to the differential amplifier 301b. The N-channel transistor 1001c has a source connected to the ground and a drain connected to the differential amplifier 301c. The N-channel transistor 1001d has a source connected to the ground and a drain connected to the differential amplifier 301d.

A switch of a control signal φ1 connects a voltage Vb2 to a gate of the transistor 1001a and connects the ground to a gate of the transistor 1001c according to the control signal φ1. A switch of a control signal /φ connects the ground to the gate of the transistor 1001a and connects the voltage Vb2 to the gate of the transistor 1001c according to the control signal /φ1. The control signals φ1 and /φ1 are signals having mutually inverted phases.

A switch of a control signal φ2 connects the voltage Vb2 to a gate of the transistor 1001b and connects the ground to a gate of the transistor 1001d according to the control signal φ2. A switch of a control signal /φ2 connects the ground to the gate of the transistor 1001b and connects the voltage Vb2 to the gate of the transistor 1001d according to the control signal /φ2. The control signals φ2 and /φ2 have mutually inverted phases.

A cycle T1 is one cycle of an oscillating operation. The transistors 1001a to 1001d are current sources. Clocks of the control signals φ1, φ2, /φ1, /φ2 each have a phase shifted by 90 degrees of the clock cycle.

For example, when being at 0 degree of the clock cycle, the control signal /φ1 turns to a high level, and the control signal φ1 turns to a low level. The gate of the transistor 1001c is supplied with the voltage Vb2, and the current source of the transistor 1001c is connected to the differential amplifier 301c. The gate of the transistor 1001a is supplied with the ground, and the current source of the transistor 1001c is disconnected from the differential amplifier 301a.

When being at 90 degrees of the clock cycle, the control signal /φ2 turns to a high level, and the control signal φ2 turns to a low level. The gate of the transistor 1001d is supplied with the voltage Vb2, and the current source of the transistor 1001d is connected to the differential amplifier 301d. The gate of the transistor 1001b is supplied with the ground, and the current source of the transistor 1001b is disconnected from the differential amplifier 301b.

When being at 180 degrees of the clock cycle, the control signal φ1 turns to a high level, and the control signal /φ1 turns to a low level. The gate of the transistor 1001a is supplied with the voltage Vb2, and the current source of the transistor 1001a is connected to the differential amplifier 301a. The gate of the transistor 1001c is supplied with the ground, and the current source of the transistor 1001c is disconnected from the differential amplifier 301c.

When being at 270 degrees of the clock cycle, the control signal φ2 turns to a high level, and the control signal /φ2 turns to a low level. The gate of the transistor 1001b is supplied with the voltage Vb2, and the current source of the transistor 1001b is connected to the differential amplifier 301b. The gate of the transistor 1001d is supplied with the ground, and the current source of the transistor 1001d is disconnected from the differential amplifier 301d.

The current sources 1001a and 1001c correspond to the current source 603c of FIG. 6A. When the current source 1001a is in a connected state, the current source 1001c is in a disconnected state, and when the current source 1001c is in a connected state, the current source 1001a is in a disconnected state. Specifically, the current sources 1001a and 1001c are connected alternately to the differential amplifiers 301a and 301c respectively, where only one of them turns to a connected state and the other one turns to a disconnected state. As explained in the first embodiment, only one of the differential amplifiers 301a and 301c turns to an amplifying operation state, and turning of the both to an amplifying operation state simultaneously does not occur.

Similarly, the current sources 1001b and 1001d correspond to the current source 603b of FIG. 6A. When the current source 1001b is in a connected state, the current source 1001d is in a disconnected state, and when the current source 1001d is in a connected state, the current source 1001b is in a disconnected state. Specifically, the current sources 1001b and 1001d are connected alternately to the differential amplifiers 301b and 301d respectively, where only one of them turns to a connected state and the other one turns to a disconnected state. Only one of the differential amplifiers 301b and 301d turns to an amplifying operation state, and turning of the both to an amplifying operation state simultaneously does not occur.

In this embodiment, until the PLL locks up, the current sources 1001a to 1001d are all kept on, and in a steady state after the lock up, the current consumption can be cut in half by controlling the switches with the clocks as in FIG. 11.

In this embodiment, by switching-controlling the tail current sources 1001a to 1001d without sharing the current sources, the operation similar to the first to fifth embodiments can be performed. In the case of the switching operation, by controlling with the clocks at timings as in FIG. 11, the current consumption amount can be cut in half.

When there are switches at the gates of the tail current sources 1001a to 1001d, the switch of a ring element having a phase shifted by 90 degrees may be in an off state when the current sources 1001a to 1001d having certain phases are in an on state. In this case, it is necessary to control on/off of the switches externally, and it is necessary to perform control with a frequency that is two-fold of the oscillation frequency of the VCO.

FIG. 12A is a circuit diagram showing a structure example of a quadrature LC-VCO. The quadrature LC-VCO has a circuit structured by arranging two CML type LC-VCOs (oscillating units) 1201a and 1201b side-by-side and further coupling them to each other. The LC-VCO 1201a and 1201b change in oscillation frequency according to the control voltage Vcntl, amplify differential signals inputted from a non-inverting input terminal I+ and an inverting input terminal I−, and output the amplified differential signals from a non-inverting output terminal O+ and an inverting output terminal O−. The LC-VCO 1201a outputs differential signals of 0 degree and 180 degrees from the output terminals O+ and O−. The LC-VCO 1201b outputs differential signals of 270 degrees and 90 degrees from the output terminals O+ and O−.

A low-pass filter 1202a is connected between the output terminal O− of the LC-VCO 1201b and the input terminal I+ of the LC-VCO 1201a. A low-pass filter 1202b is connected between the output terminal O+ of the LC-VCO 1201a and the input terminal I+ of the LC-VCO 1201b. A low-pass filter 1202c is connected between the output terminal O+ of the LC-VCO 1201b and the input terminal I− of the LC-VCO 1201a. A low-pass filter 1202d is connected between the output terminal O− the LC-VCO 1201a and the input terminal I− of the LC-VCO 1201b. The low-pass filters 1202a to 1202d passes only a signal in a low frequency band, and hence the delay amount thereof changes according to a frequency.

FIG. 12B is a circuit diagram showing a structure example of each of the LC-VCOs 1201a and 1201b of FIG. 12A. The LC-VCOs 1201a and 1201b each have a resonance circuit of an inductor 1212 and capacitors 1213a, 1213b, a CML type differential amplifier including input differential pair transistors 1216a, 1216b, and negative resistors 1214a, 1214b.

The P-channel transistor 1211a has a gate connected to the non-inverting output terminal O+, a source connected to the power supply voltage, and a drain connected to the inverting output terminal O−. A P-channel transistor 1211b has a gate connected to the inverting output terminal O−, a source connected to the power supply voltage, and a drain connected to a non-inverting output terminal O+. The inductor 1212 is connected between the output terminals O+ and O−. The variable capacitor 1213a is connected between the control voltage Vcntl and the inverting output terminal O−, and has a capacitance value that changes according to the control voltage Vcntl. The variable capacitor 1213b is connected between the control voltage Vcntl and the non-inverting output terminal O+, and has a capacitance value that changes according to the control voltage Vcntl. The N-channel transistor 1214a has a gate connected to the output terminal O+, a drain connected to the output terminal O−, and a source connected to the ground via the current source 1215. The N-channel transistor 1214b has a gate connected to the output terminal O−, a drain connected to the output terminal O+, and a source connected to the ground via the current source 1215. The N-channel transistor 1216a has a gate connected to the non-inverting input terminal I+, a drain connected to the output terminal O−, and a source connected to the ground via a current source 1217. The N-channel transistor 1216b has a gate connected to the inverting input terminal I−, a drain connected to the output terminal O+, and a source connected to the ground via the current source 1217. The transistors 1216a and 1216b form an input differential pair transistor. A current Irer1 flowing through the current source 1215 and a current Iref2 flowing through the current source 1217 are variable or fixed according to the control voltage Vcntl. This LC-VCO oscillates by LC resonance. The oscillation frequency thereof changes by controlling the control voltage Vcntl.

This LC-VCO has the two tail current sources 1215 and 1217 of CML. The current source 1215 is a current source used for the LC resonance. The current source 1217 is a current source that determines the strength of connection for realizing the coupling. When the ratio of the resonance current Iref1 to the current Iref2 of coupling is optimized, the LC-VCOs 1201a and 1201b result in outputting of signals having a phase difference relationship of 90 degrees in resonance frequencies determined by LC. A resonance frequency fo of the LC-VCO is represented by the following equation.

fo=1/(2×π×√(L×C))

The LC-VCO is constituted of the LC resonance circuit and the negative resistance circuit units 1211a, 1211b, 1214a, 1215b, and a condition to oscillate is as follows.

gm×Rp≧1

Here, it is assumed that a resistance value obtained from an equivalent circuit of the LC resonance unit is Rp, and an impedance of the negative resistance units is −1/gm. Now, the role of the tail current source 1215 of CML of the resonance circuit is to make a bias current and not to allow the resistance value to be low when a switching transistor enters a linear region.

The LC-VCO operates in the above-described oscillation frequency as long as the above oscillation condition is satisfied.

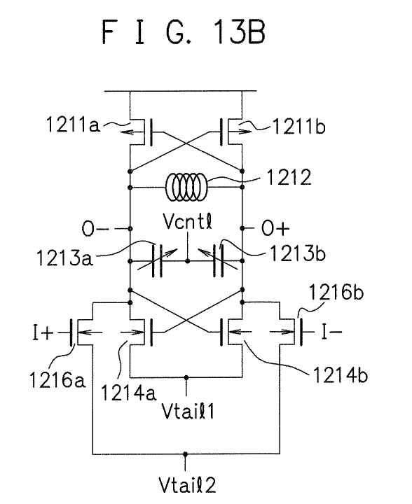

FIG. 13A is a circuit diagram showing a configuration example of the VCO 104 (FIG. 1 and FIG. 2) according to the seventh embodiment of the present invention. Similarly to the first to fifth embodiments, this embodiment is a quadrature LC-VCO in which the two LC-VCOs 1201a and 1201b share the current sources 1301a and 1301b. Differences of FIG. 13A from FIG. 12A will be explained. The LC-VCOs 1201a and 1201b have terminals Vtail1, Vtail2 besides the input terminals I+, I− and output terminals O+, O−. The current source 1301a is connected between the terminals Vtail1 of the LC-VCOs 1201a and 1201b and the ground, and allows the current Iref1 to flow. The current source 1301b is connected between the terminals Vtail2 of the LC-VCOs 1201a and 1201b and the ground, and allows the current Iref2 to flow.

FIG. 13B is a circuit diagram showing a structure example of each of the LC-VCOs 1201a and 1201b of FIG. 13A. Differences of FIG. 13B from FIG. 12B will be explained. The terminals Vtail1 and Vtail2 are provided instead of the current sources 1215 and 1217 of FIG. 12B. The terminal Vtail1 is connected to a mutual connection point of sources of transistors 1214a and 1214b. In other words, the mutual connection point of the sources of the transistors 1214a and 1214b is connected to the current source 1301a of FIG. 13A via the terminal Vtail1. The terminal Vtail2 is connected to a mutual connection point of sources of the transistors 1216a and 1216b. In other words, the mutual connection point of the sources of the transistors 1216a and 1216b is connected to the current source 1301b of FIG. 13A via the terminal Vtail2.

In the circuits of FIG. 12A and FIG. 12B, the two LC-VCOs 1201a and 1201b each have the two current sources 1215 and 1217 individually. In comparison, in the circuits of FIG. 13A and FIG. 13B, the two LC-VCOs 1201a and 1201b are connected to the common current sources 1301a and 1301b. The current sources 1301a and 1301b of FIG. 13A correspond to the current sources 1215 and 1217 of FIG. 12B respectively.

The LC-VCOs 1201a and 1201b output differential signals with phases in a mutually orthogonal relationship, and therefore, similarly to the first to fifth embodiments, they can share the current sources 1301a and 1301b.

The quadrature LC-VCO of FIG. 13A can cut the current consumption in half. Since the phase difference relationship of 90 degrees is ensured between the two LC-VCOs 1201a and 1201b, the quadrature LC-VCO can cut the current consumption in half by sharing the tail current sources 1301a and 1301b of the LC-VCOs 1201a and 1201b.

In the quadrature LC-VCO, the LC-VCOs 1201a and 1201b each oscillate by the differential signals, and by coupling these signals, the phase relationship of 90 degrees are maintained. The two LC-VCOs 1201a and 1201b are certainly in the phase difference relationship of 90 degrees, and it is possible to allow the tail current sources 1301a and 1301b thereof to be shared.

The quadrature LC-VCO is constituted of the tail current source 1301a for oscillation of the LC-VCOs and the tail current source 1301b for coupling the LC-VCOs. Since the LC-VCOs 1201a and 1201b have the phase difference relationship of 90 degrees, they can share the current sources 1301a and 1301b.

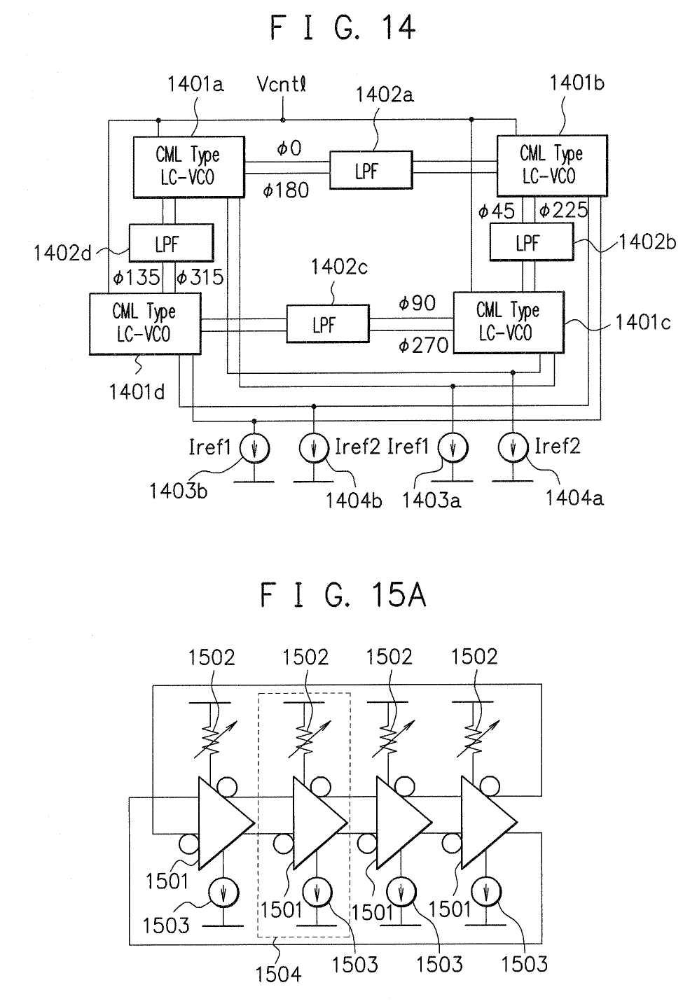

FIG. 14 is a circuit diagram showing a configuration example of the VCO 104 (FIG. 1 and FIG. 2) according to an eighth embodiment of the present invention. In the seventh embodiment, the quadrature LC-VCO coupling the two CML type LC-VCOs is shown, but in this embodiment, a multi-phase LC-VCO coupling four CML type LC-VCOs 1401a to 1401d is shown.

The LC-VCOs 1401a to 1401d each have the same structure as FIG. 13B. The LC-VCO 1401a outputs differential signals of 0 degree and 180 degrees. The LC-VCO 1401b outputs differential signals of 45 degrees and 225 degrees. The LC-VCO 1401c outputs differential signals of 90 degrees and 270 degrees. The LC-VCO 1401d outputs differential signals of 135 degrees and 315 degrees. The LC-VCOs 1401a to 1401d change in oscillation frequency according to the control voltage Vcntl.

A low-pass filter 1402a is connected between output terminals of the LC-VCO 1401a and input terminals of the LC-VCO 1401b. A low-pass filter 1402b is connected between output terminals of the LC-VCO 1401b and input terminals of the LC-VCO 1401c. A low-pass filter 1402c is connected between output terminals of the LC-VCO 1401c and input terminals of the LC-VCO 1401d. A low-pass filter 1402d is connected between output terminals of the LC-VCO 1401d and input terminals of the LC-VCO 1401a.

A current source 1403a is connected between terminals Vtail1 of the LC-VCOs 1401a and 1401c and the ground. A current source 1404a is connected between terminals Vtail2 of the LC-VCOs 1401a and 1401c and the ground. A current source 1403b is connected between terminals Vtail1 of the LC-VCOs 1401b and 1401d and the ground. A current source 1404b is connected between terminals Vtail2 of the LC-VCOs 1401b and 1401d and the ground. The current sources 1403a and 1403b allow a current Iref1 to flow. The current sources 1404a and 1404b allow a current Iref2 to flow.

The LC-VCOs 1401a and 1401c output differential signals with phases having a mutually orthogonal relationship, and therefore they can share the current sources 1403a and 1404a. Similarly, the LC-VCOs 1401b and 1401d output differential signals with phases having a mutually orthogonal relationship, and therefore they can share the current sources 1403b and 1404b.

In the case of the LC-VCOs, similarly to the ring oscillator type VCO, a multi-phase can be created by the number of LC-VCOs. When a plurality of (two or more) LC-VCOs are arranged side-by-side, this makes the phase shift amount to change, similarly to the ring oscillator type VCO.

The plurality of LC-VCOs (CML type differential amplifiers) are coupled. Output signals of each of the coupled LC-VCOs (CML type differential amplifiers) have a phase difference resulting from dividing 180 degrees by the number of coupled LC-VCOs (CML type differential amplifiers). Also in this case, the LC-VCOs having the phase difference relationship of 90 degrees share the current sources, and hence the current consumption can be cut in half.

As described above, according to the first to eighth embodiments, simultaneous connection of a plurality of current sources to a plurality of ring elements or a plurality of LC-VCOs does not occur, and only one current source is connected thereto at any point of time. In the ring-oscillator type VCOs or LC-VCOs of CML type having phases in an orthogonal relationship, the differential amplifiers in an orthogonal relationship share the tail current sources, and thereby the current consumption can be cut in half. Even when the tail current sources are shared, the same oscillation condition and oscillation frequency as those when the tail current sources are not shared are kept. In other words, the VCOs can obtain desired voltage-frequency characteristics by the same oscillation condition as when not sharing the tail current sources, and thereby only the current consumption can be cut in half.

The above-described embodiments are applicable to a VCO to be a signal source for a fast I/O circuit and an RF mixer in a bipolar or CMOS technology.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

### INDUSTRIAL APPLICABILITY

First and second oscillating units outputting signals having phases in a mutually orthogonal relationship are different from each other in time of consuming a current. A current source allows only a necessary current to flow, and hence the current consumption can be made small.

What is claimed is:

1. An oscillator comprising first and second oscillating units outputting signals having phases in a mutually orthogonal relationship,
wherein simultaneous connection of a plurality of current sources to said first and second oscillating units does not occur, and only one current source is connected thereto at any point of time.

2. The oscillator according to claim 1,
wherein said current source is connected in common to said first and second oscillating units, and
wherein said first and second oscillating units each have a CML type differential amplifier including a delay element of a resistor and a capacitor and form a ring oscillator to be ring connected.

3. The oscillator according to claim 2, wherein said current source and said resistor are variable according to a control voltage.

4. The oscillator according to claim 2,
wherein said resistor is connected to a power supply voltage, and
wherein said current source uses an N-channel field effect transistor connected between said CML type differential amplifier and ground.

5. The oscillator according to claim 2,
wherein said resistor is connected to ground, and
wherein said current source uses a P-channel field effect transistor connected between said CML type differential amplifier and a power supply voltage.

6. The oscillator according to claim 2, wherein said current source has a first current source connected between said CML type differential amplifier and a power supply voltage, and a second current source connected between said CML type differential amplifier and ground.

7. The oscillator according to claim 2, wherein output signals of each of said ring connected CML type differential amplifiers have a phase difference resulting from dividing 180 degrees by the number of said ring connected CML type differential amplifiers.

8. The oscillator according to claim 1,
wherein there are two of said current sources,
wherein said two current sources are connected alternately to said first and second oscillating units respectively, and
wherein said first and second oscillating units each have a CML type differential amplifier including a delay element of a resistor and a capacitor and form a ring oscillator to be ring connected.

9. The oscillator according to claim 2, wherein said first oscillating unit outputs differential signals of 0 degree and 180 degrees, and said second oscillating unit outputs differential signals of 90 degrees and 270 degrees.

10. The oscillator according to claim 9, further comprising:
a third oscillating unit having a CML type differential amplifier including a delay element of a resistor and a capacitor and outputting differential signals of 45 degrees and 225 degrees; and
a fourth oscillating unit having a CML type differential amplifier including a delay element of a resistor and a capacitor and outputting differential signals of 135 degrees and 315 degrees.

11. The oscillator according to claim 9, further comprising:
a third oscillating unit having a CML type differential amplifier including a delay element of a resistor and a capacitor and outputting differential signals of 30 degrees and 210 degrees;
a fourth oscillating unit having a CML type differential amplifier including a delay element of a resistor and a capacitor and outputting differential signals of 60 degrees and 240 degrees;
a fifth oscillating unit having a CML type differential amplifier including a delay element of a resistor and a capacitor and outputting differential signals of 120 degrees and 300 degrees; and
a sixth oscillating unit having a CML type differential amplifier including a delay element of a resistor and a capacitor and outputting differential signals of 150 degrees and 330 degrees.

12. An oscillator comprising first and second oscillating units each having a resonance circuit of an inductor and a capacitor, a CML type differential amplifier including input differential pair transistors, and a negative resistor, and outputting signals having phases in a mutually orthogonal relationship,
wherein simultaneous connection of a plurality of current sources to the negative resistors of said first and second oscillating units does not occur, and only one first current source is connected thereto at any point of time, and
wherein simultaneous connection of a plurality of current sources to the input differential pair transistors of said first and second oscillating units does not occur, and only one second current source is connected thereto at any point of time.

13. The oscillator according to claim 12,
wherein said first current source is connected in common to the negative resistors of said first and second oscillating units, and
wherein said second current source is connected in common to the input differential pair transistors of said first and second oscillating units.

14. The oscillator according to claim 13,
wherein said plurality of CML type differential amplifiers are coupled, and
wherein output signals of each of said coupled CML type differential amplifiers have a phase difference resulting from dividing 180 degrees by the number of said coupled CML type differential amplifiers.

15. The oscillator according to claim 14, further comprising a low-pass filter connected between said plurality of CML type differential amplifiers.

16. The oscillator according to claim 13, wherein said capacitor is variable according to a control voltage.

17. The oscillator according to claim 13, wherein said first oscillating unit outputs differential signals of 0 degrees and 180 degrees, and said second oscillating unit outputs differential signals of 90 degrees and 270 degrees.

18. The oscillator according to claim 17, further comprising:
a third oscillating unit having a resonance circuit of an inductor and a capacitor, a CML type differential amplifier including input differential pair transistors, and a negative resistor, and outputting differential signals of 45 degrees and 225 degrees; and
a fourth oscillating unit having a resonance circuit of an inductor and a capacitor, a CML type differential amplifier including input differential pair transistors, and a negative resistor, and outputting differential signals of 135 degrees and 315 degrees.
